(19) United States
(12) Patent Application Publication
(10) Pub. No.: US 2010/0213599 A1
(43) Pub. Date: Aug. 26, 2010

(54) SEMICONDUCTOR DEVICE AND MANUFACTURING METHOD THEREOF

(75) Inventors: Kazuhiro Watanabe, Nakano-ku (JP); Seiki Takata, Yokohama-shi (JP); Toshitsune Iijima, Tama-shi (JP); Tomomi Sato, Ota-ku (JP); Shigenori Sawachi, Hiratsuka-shi (JP); Takumi Kawana, Kawasaki-shi (JP); Osamu Yamagata, Ota-ku (JP); Hiroshi Nomura, Yokosuka-shi (JP); Yumiko Oshima, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/704,094

(22) Filed: Feb. 11, 2010

(30) Foreign Application Priority Data
Feb. 20, 2009 (JP) 2009037552
Sep. 25, 2009 (JP) 2009220112

(51) Int. Cl. H01L 23/498; H01L 21/60

(52) U.S. Cl. 257/693; 438/107; 257/E23.068; 257/E21.506

(57) ABSTRACT

A semiconductor device includes: a flat plate; a semiconductor chip which is disposed on one main surface of the flat plate and whose surface opposite an element circuit surface is fixedly bonded; a single layer of an insulating material layer formed continuously on the element circuit surface of the semiconductor chip and on the main surface of the flat plate; an opening formed at a position, in the insulating material layer, above an electrode disposed on the element circuit surface of the semiconductor chip; a conductive part formed in the opening so as to be connected to the electrode of the semiconductor chip; a wiring layer formed on the insulating material layer so as to be connected to the conductive part, and partly led out to a peripheral area of the semiconductor chip; and external electrodes formed on the wiring layer. Also adoptable is a structure in which a flat plate having a cavity is used, a semiconductor chip is disposed in the cavity, and an insulating material layer is filled and formed in a gap in the cavity. A semiconductor device high in yields and connection reliability, adaptable to a microscopic pitch of electrodes of a semiconductor chip, and excellent in electric characteristic is obtained at low cost.

### CROSS-REFERENCE TO RELATED APPLICATIONS

This application is based upon and claims the benefit of priority from the prior Japanese Patent Application No. 2009-37552, filed on Feb. 20, 2009 and Japanese Patent Application No. 2009-220112 filed on Sep. 25, 2009; the entire contents of which are incorporated herein by reference.

### BACKGROUND OF THE INVENTION

In recent years, as a method of manufacturing a semiconductor device such as a LSI unit or an IC module, there is proposed a method of collectively manufacturing a plurality of semiconductor devices by molding as described below.

In this method, a plurality of semiconductor chips determined as non-defective in an electric characteristic test are first affixed in a predetermined arrangement on a holding plate, with element circuit surfaces thereof facing downward, and thereafter a resin sheet, for instance, is disposed thereon and the whole structure is heated and pressed for molding. In this manner, the plural semiconductor chips are collectively resin-sealed.

Next, the holding plate is peeled off, and after a resin sealed body is cut and processed into a predetermined shape (for example, a circular shape), an insulating resin layer is formed on the element circuit surfaces of the semiconductor chips buried in the resin sealed body and openings are formed in the insulating resin layer so as to be aligned with positions of electrode pads of the semiconductor chips. Thereafter, a wiring layer is formed on the insulating resin layer and conductive parts (via parts) connected to the electrode pads of the semiconductor chips are formed in the openings.

After the sequential formation of a solder resist layer and solder balls being external electrode terminals, each of the semiconductor chips is cut out into an individual piece, whereby a semiconductor device is completed (see, for example, JP-A 2003-197662 (KOKAI)).

However, the conventional semiconductor device thus manufactured has the following problems. Specifically, when the plural semiconductor chips are collectively resin-sealed, resin shrinks as it cures and an amount of the shrinkage is not always equal to a designed amount, which sometimes causes positional deviation from designed positions after the resin is cured, depending on arrangement positions of the semiconductor chips. In the semiconductor chip thus deviated in its position, the electrode pads of this semiconductor chip deviate in position from the via parts formed in the openings of the insulating resin layer, which leads to lowering connection reliability. Further increase in the positional deviation causes a connection failure in some semiconductor chip, which leads to lowering yields. Therefore, it has been difficult to miniaturize the electrode pads.

Further, there has been proposed a manufacturing method of a semiconductor device in which two-layers of insulating material layers are formed in a stacked manner on semiconductor chips mounted on a base, openings are formed in these layers, and via parts are formed therein (see, for example, JP-A 2005-167191 (KOKAI)). In this proposal, however, processes of forming the insulating material layers and the via parts are complicated, which not only makes it difficult to obtain high yields but also may possibly increase a stress in a package due to a difference in coefficient of thermal expansion among constituent materials.

Further, there has been proposed arts in which semiconductor chips are disposed in cavities formed in a substrate and a plurality of insulating layers and conductive layers are alternately stacked is formed on the semiconductor chips (see, for example, JP-A 2002-246756 (KOKAI), JP-A 2002-246504 (KOKAI), and JP-A 11-233678 (KOKAI)). In these arts, however, a process of forming the stacked structure is complicated, which influences a term of the work and cost, and in addition, since two parameters, namely, positional accuracy of the cavities and positional accuracy of the arrangement of the semiconductor chips are involved, positional accuracy of the semiconductor chips is poor. Further, a stress in a package ascribable to a difference in coefficient of thermal expansion between the semiconductor chips and an insulating base material becomes large, which leads to low reliability. Further, there has been proposed a semiconductor device in which wiring (re-wiring) is formed on semiconductor elements on a wafer level (see, for example, JP-A 2001-332643 (KOKAI) and JP-A 2001-217381 (KOKAI)). These semiconductor devices, however, have a problem of difficulty in a mounting work since it is not possible to lead a wiring layer to a peripheral area outside the semiconductor elements and thus the pitch of external electrodes becomes narrow.

### BRIEF SUMMARY OF THE INVENTION

A semiconductor device according to one aspect of the present invention comprises: a flat plate; a semiconductor chip which is disposed on one main surface of the flat plate and whose surface opposite an element circuit surface is fixedly bonded; a single layer of an insulating material layer formed continuously on the element circuit surface of the semiconductor chip and on the main surface of the flat plate and composed of a material different from a material of the flat plate; an opening formed at a position, in the insulating material layer, above an electrode disposed on the element circuit surface of the semiconductor chip; a conductive part formed in the opening so as to be connected to the electrode of the semiconductor chip; a wiring layer formed on the insulating material layer so as to be connected to the conductive part, and partly led out to a peripheral area of the semiconductor chip; and external electrodes formed on the wiring layer.

A method of manufacturing a semiconductor device according to a second aspect of the present invention comprises: on one main surface of a flat plate, positioning and disposing a plurality of semiconductor chips and fixedly bonding surfaces, of the semiconductor chips, opposite element circuit surfaces; forming an insulating material layer composed of a material different from a material forming the flat plate, on the element circuit surfaces of the semiconductor chips and on the main surface of the flat plate; forming openings in the insulating material layer at positions above electrodes disposed on the element circuit surfaces of the semiconductor chips; forming, on the insulating material layer, a wiring layer partly led out to peripheral areas of the semiconductor chips, and forming, in the openings of the insulating material layer, conductive parts connected to the electrodes of the semiconductor chips; forming external electrodes on the wiring layer; and cutting the flat plate and the insulating material layer at predetermined positions to separate a semiconductor device including one or more of the semiconductor chips.

### BRIEF DESCRIPTION OF THE DRAWINGS

FIG. 1 is a cross-sectional view showing a first embodiment of a semiconductor device according to the present invention.

FIG. 2A to FIG. 2F are cross-sectional views showing processes of a method of manufacturing the semiconductor device according to the first embodiment of the present invention.

FIG. 3 is a cross-sectional view showing a second embodiment of the semiconductor device according to the present invention.

FIG. 4 is a cross-sectional view showing a third embodiment of the semiconductor device according to the present invention.

FIG. 5 is a cross-sectional view showing a structure in which a grounding via part is formed in an end portion of the semiconductor device, in the third embodiment.

FIG. 6 is a cross-sectional view showing a fourth embodiment of the semiconductor device according to the present invention.

FIG. 7 is a cross-sectional view showing a fifth embodiment of the semiconductor device according to the present invention.

FIG. 8A to FIG. 8F are cross-sectional views showing processes of a method of manufacturing the semiconductor device according to the fifth embodiment of the present invention.

FIG. 9 is a cross-sectional view showing a sixth embodiment of the semiconductor device according to the present invention.

FIG. 10 is a cross-sectional view showing a seventh embodiment of the semiconductor device according to the present invention

FIG. 11 is a cross-sectional view showing an eighth embodiment of the semiconductor device according to the present invention.

FIG. 12 is a cross-sectional view showing a ninth embodiment of the semiconductor device according to the present invention.

FIG. 13 is a cross-sectional view showing a tenth embodiment of the semiconductor device according to the present invention.

FIG. 14 is a cross-sectional view showing an eleventh embodiment of the semiconductor device according to the present invention.

FIG. 15A to FIG. 15F are cross-sectional views showing processes of a method of manufacturing the semiconductor device according to the eleventh embodiment of the present invention.

FIG. 16 is a cross-sectional view showing a twelfth embodiment of the semiconductor device according to the present invention.

FIG. 17 is a cross-sectional view showing a thirteenth embodiment of the semiconductor device according to the present invention.

### DETAILED DESCRIPTION OF THE INVENTION

Hereinafter, embodiments for carrying out the present invention will be described. The embodiments will be described with reference to drawings, which are provided for illustration only, and the present invention is not limited to the drawings.

### First Embodiment

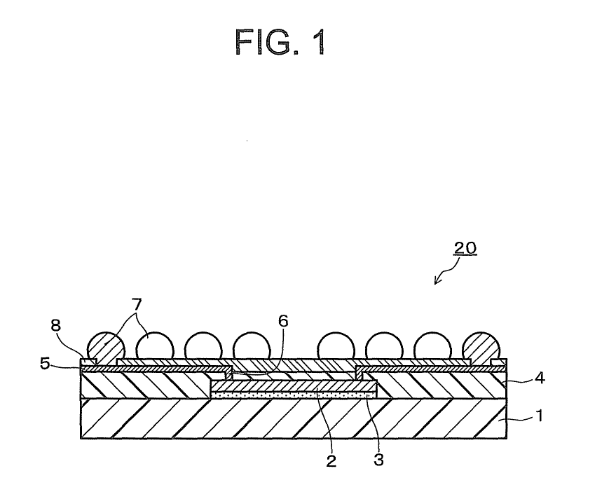

FIG. 1 is a vertical cross-sectional view showing a first embodiment of the semiconductor device according to the present invention. A semiconductor device 20 of the first embodiment includes a flat plate 1 of a resin cured substance or metal. The flat plate 1 is a planar plate having a uniform thickness and is made of a resin cured substance which is cured insulating resin or from metal such as stainless steel or a 42 alloy. The thinner the thickness of the flat plate 1 is, the better, but the flat plate 1 preferably has a thickness large enough to prevent warpage caused by the formation of a later-described insulating material layer.

On one main surface of the flat plate 1, a semiconductor chip 2 determined as non-defective in an electric characteristic test is disposed with an element circuit surface thereof facing upward and a surface (rear surface) opposite the element circuit surface is fixedly bonded on the flat plate 1 by an adhesive 3. When the flat plate 1 is made of a resin cured substance, thermo-setting epoxy resin or the like is used as the adhesive 3. When the flat plate 1 is made of metal, solder paste or the like is used as the adhesive 3. On the entire main surface of the flat plate 1, only one layer of an insulating material layer 4 is formed so as to cover the element circuit surface of the semiconductor chip 2.

In order for the insulating material layer 4 to be a single layer (one layer) having a smooth surface free from irregularities, the thickness of the semiconductor chip 2 is preferably 20 μm or less. Further, a height from a semiconductor chip mounting surface being the main surface of the flat plate 1 to an upper surface (element circuit surface) of the semiconductor chip 2 is preferably 100 μm or less, more preferably 50 μm less. This height is the sum of the thickness of the semiconductor chip 2 and the thickness of a layer of the adhesive 3. When the thickness of the semiconductor chip 2 is 20 μm or less and the height from the main surface of the flat plate 1 to the upper surface of the semiconductor chip 2 is 50 μm or less, it is possible to form a single layer of the insulating material layer 4 having the smooth surface free from irregularities on the flat plate 1 on which the semiconductor chip 2 is mounted, only by one coating of liquid resin such as photosensitive epoxy resin using a spin coater or the like.

When the thickness of the semiconductor chip 2 is over 20 μm and the height from the main surface of the flat plate 1 to the upper surface of the semiconductor chip 2 is over 100 μm, irregularities are likely to occur in a surface (upper surface) of the insulating material layer 4 covering these surfaces and formed thereon, and thus a problem in exposure and development (exposure blur) is likely to occur in a photosensitive resist used in forming a wiring layer 5 on the insulating material layer 4, which is not desirable. When the sum of the thickness of the semiconductor chip 2 and the thickness of the layer of the adhesive 3, even if over 50 μm, is less than 100 μm, it is possible to form a single layer of the insulating material layer 4 having the smooth surface free from irregularities, by repeating the coating by a spin coater or the like a plurality of times or by pressure-bonding and curing a plurality of insulating films.

The insulating material layer 4 is composed of a material different from the material forming the flat plate 1 and has the smooth surface free from irregularities. For example, it can be formed by a method of spin-coating photosensitive epoxy resin. A portion, of the insulating material layer 4, formed on the element circuit surface of the semiconductor chip 2 preferably has a sufficiently small thickness, concretely, 5 μm to 30 μm, more preferably, 10 μm to 20 μm.

On a single layer of the insulating material layer 4, the wiring layer 5 made of conductive metal such as copper is formed, and part thereof is led out to a peripheral area of the semiconductor chip 2. Further, in the insulating material layer 4 formed on the element circuit surface of the semiconductor chip 2, via parts 6 electrically connecting electrode pads (not shown) of the semiconductor chip 2 and the wiring layer 5 are formed. The via parts 6 are formed collectively with the wiring layer 5 and are integrated with the wiring layer 5.

Further, a plurality of solder balls 7 being external electrodes are formed at predetermined positions of the wiring layer 5. Since the wiring layer 5 on the insulating material layer 4 is partly led out to the peripheral area of the semiconductor chip 2 as previously described, the solder balls 7 are arranged in a grid array over the entire area of the flat plate 1 including the peripheral area of the semiconductor chip 2. The solder balls 7 thus arranged and formed in a grid array are called BGA balls. Further, on the insulating material layer 4 and on the wiring layer 5 except joint portions of the solder balls 7, a protective layer such as a solder resist layer 8 is formed.

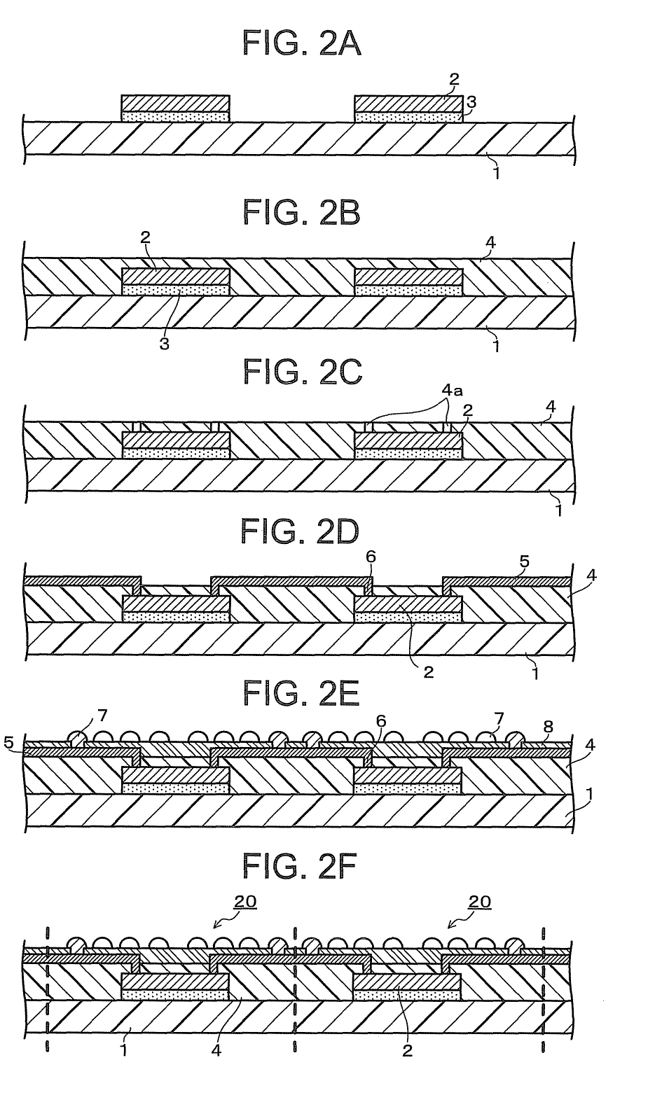

A method of manufacturing the above-described semiconductor device 20 of the first embodiment is shown below. First, as shown in FIG. 2A, on the one main surface of the flat plate 1 made of a resin cured substance or metal, a plurality of the semiconductor chips 2 determined as non-defective in the electric characteristic test are positioned and disposed at predetermined arrangement positions, with the element circuit surfaces thereof facing upward. Then, the surfaces opposite the element circuit surfaces of the semiconductor chips 2 are bonded and fixed on the main surface of the flat plate 1 by the adhesive 3.

As shown in FIG. 2B, an insulating resin material such as photosensitive epoxy resin different from the material forming the flat plate 1 is applied (coating) once on the whole main surface of the flat plate 1 including the element circuit surfaces of the plural semiconductor chips 2 fixedly bonded, by using, for example, a spin coater, whereby a single layer (one layer) of the insulating material layer 4 having the smooth surface free from irregularities is formed. A printing method using a squeegee may be employed for the coating of the insulating resin material.

Next, as shown in FIG. 2C, openings 4a are formed at positions, in the insulating material layer 4, above the electrode pads of the semiconductor chip 2 by using photolithography. Preferably, processes after the formation of the openings 4a come after an insulating material-covered body in which the insulating material layer 4 is formed so as to collectively cover the plural semiconductor chips 2 in the previous process is cut and processed into a predetermined shape (for example, a circular wafer shape). Such cutting and processing into the circular shape or the like makes it possible to perform subsequent processes in the same manner as formation processes used in a semiconductor wafer manufacture.

Next, on the whole upper surface of the insulating material layer 4, a layer of conductive metal such as copper is formed by an electrolytic plating method or the like. At this time, as shown in FIG. 2D, the conductive metal layer is also formed in the openings 4a of the insulating material layer 4, so that the via parts 6 electrically connecting the electrode pads of the semiconductor chips 2 and the conductive metal layer on the insulating material layer 4 are formed. Next, the conductive metal layer formed on the whole surface is patterned by photolithography to form the wiring layer 5. The patterning by photolithography can be performed in such a manner that after a photosensitive resist layer is formed on the conductive metal layer and it is exposed and developed by using a mask with a predetermined pattern, the conductive metal layer is etched. This electrolytic plating and patterning by photolithography make it possible to collectively form the via parts 6 electrically connected to the electrode pads of the semiconductor chips 2, the wiring layer 5, and predetermined portions of the wiring layer 5 on which the solder balls 7 may be formed in a later process.

As shown in FIG. 2E, the protective layer such as the solder resist layer 8 is formed on the insulating material layer 4 and on predetermined areas in the wiring layer 5 except connection pads of the external electrodes. The solder resist layer 8 can be formed by, for example, a method in which solder resist is applied on the whole surface and thereafter openings are formed in predetermined portions (above the connection pads of the external electrodes) or a method such as screen printing or the like. Next, the solder balls 7 being the external electrodes are formed in the openings of the solder resist layer 8.

In a pseudo wafer structure which is obtained in such a manner that the plural semiconductor chips 2 thus cut out into individual pieces from a semiconductor wafer and determined as non-defective are re-arranged on the flat plate 1 and bonded and fixed thereon, processes such as resin sealing, the formation of the via openings, the formation of the via parts and the wiring layer, the formation of the solder balls, and so on are performed. Thereafter, as shown in FIG. 2F, the flat plate 1, the insulating material layer 4, and so on are cut (dicing) at positions between the semiconductor chips 2, so that the semiconductor devices 20 are separated from one another. In this manner, the semiconductor device 20 of the first embodiment is completed. Forming grooves in advance at the positions of the dicing on a rear surface of the flat plate 1 facilitates the cutting and separating of the semiconductor devices 10 into individual pieces. Further, in such a case where the completed semiconductor device 20 has too large a thickness due to a reason that the thickness of the flat plate 1 is made large for warpage prevention, it is possible to reduce the thickness of the semiconductor device 20 by, for example, mechanically polishing the surface (rear surface) opposite the semiconductor chip 2 mounting surface of the flat plate 1.

In the semiconductor device 20 of the first embodiment, the insulating material layer 4 is formed collectively on the structure in which the plural semiconductor chips 2 determined as non-defective are positioned and fixedly bonded on the flat plate 1 made of a resin cured substance or metal, and in the insulating material layer 4 thus formed, the via parts 6 are formed at the positions of the electrode pads of the semiconductor chips 2, which makes it difficult for positional deviation of the electrode pads of the semiconductor chips 2 and the via parts 6 to occur. Therefore, in all the semiconductor chips 2, a joint state of the electrode pads and the via parts 6 becomes good. Consequently, the semiconductor device 20 which has high yields and high reliability and is adaptable to the miniaturization can be obtained at low cost.

Further, in the first embodiment, the thickness of the semiconductor chip 2 is 20 μm or less and the height from the main surface of the flat plate 1 to the element circuit surface of the semiconductor chip 2 is 100 μm or less, more preferably 50 μm or less, and the insulating material layer 4 having the smooth surface free from irregularities is formed, and therefore, no problem in exposure and development (exposure blur) occurs in the photosensitive resist which is formed when the wiring layer 5 and so on are formed on the insulating material layer 4. Therefore, the wiring layer 5 with a good characteristic can be formed. Further, the insulating material layer 4 is a single layer which is formed by only one coating process by using the photosensitive material different from the material forming the flat plate 1, and only one layer of such an insulating material layer 4 is formed. This has an advantage over the structure having two layers of the insulating material layers or more, in that the formation process can be simplified, yields are improved, and a stress in the package ascribable to a difference in coefficient of thermal expansion among the constituent materials can be reduced.

Furthermore, since the insulating material layer 4 formed on the element circuit surface of the semiconductor chip 2 has a small thickness (for example, 5 μm to 30 μm, preferably 10 μm to 20 μm), it is possible to reduce the diameter of the via openings 4a formed in the insulating material layer 4 (for example, 70 μm or less), and it is also possible to form the via parts 6 with a diameter as small as about 10 μm. This makes it possible to cope with the miniaturization of the electrode pads of the semiconductor chip 2 and mount the semiconductor chip 2 having the electrode pads with a small pitch of 50 μm or less. Furthermore, since the wiring layer 5 is led out also to the peripheral area of the semiconductor chip 2 and the solder balls 7 being the external electrodes are disposed also on the wiring layer 5 in this peripheral area, it is possible to arrange the solder balls 7 in a wide area and increase an arrangement pitch compared with a conventional semiconductor device in which wiring is formed on a wafer-level semiconductor element. This allows arbitrary designing of the pitch and number of the BGA balls and makes it possible to cope with the miniaturization of the electrode pads.

Next, other embodiments of the present invention will be described based on the drawings. Note that in the drawings showing the embodiments below, the same parts as those in FIG. 1 and FIG. 2 showing the semiconductor device of the first embodiment and the method of manufacturing the same are denoted by the same reference numerals and symbols, and description thereof will be omitted.

### Second Embodiment

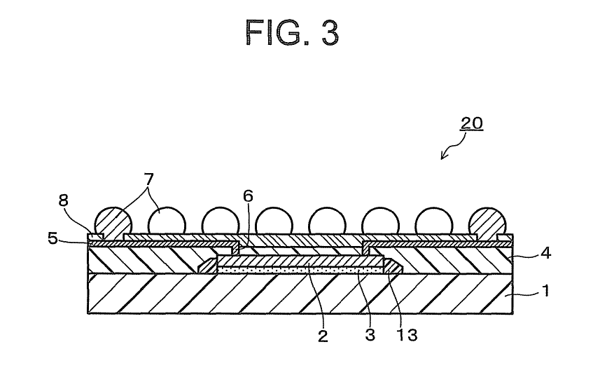

FIG. 3 is a cross-sectional view showing a second embodiment of the present invention. In the second embodiment, the sum of the thickness of a semiconductor chip 2 and the thickness of a layer of an adhesive 3 is over a predetermined value and is large (for example, more than 50 μm and equal to or less than 100 μm). A step interpolation part 13 is provided so as to surround an outer peripheral side surface of the semiconductor chip 2. The step interpolation part 13 is composed of an insulating material of the same type as or of a different type from the adhesive 3 fixedly bonding the semiconductor chip 2 and is formed thicker than the thickness of the adhesive 3. As a method of forming the step interpolation part 13, there are a method in which a liquid adhesive is used as the adhesive 3 and when the semiconductor chip 2 is fixedly bonded on a flat plate 1, the adhesive 3 is forced out from an outer periphery of the semiconductor chip 2 to be formed as the step interpolation part 13, a method in which the semiconductor chip 2 is pressed against and bonded on the adhesive 3 in a film form which is formed larger than an outside dimension of the semiconductor chip 2 and the adhesive 3 around an abutting portion is mounded up to be formed as the step interpolation part 13, a method in which, after the semiconductor chip 2 is fixedly bonded on the flat plate 1, liquid paste of the same type as or of a different type from the adhesive 3 is applied on an outer peripheral side portion of the semiconductor chip 2 to be formed as the step interpolation part 13. The other parts in the second embodiment are structured similarly to those of the first embodiment, and description thereof will be omitted.

In the second embodiment, the step interpolation part 13 formed to surround the outer peripheral side portion of the semiconductor chip 2 makes it more difficult for irregularities to be made on a surface of an insulating material layer 4 which is formed so as to cover the semiconductor chip 2. Therefore, even when the thickness sum of the semiconductor chip 2 and the adhesive 3 is over a predetermined value (for example, 50 μm), the overlaying and forming of the insulating material layer 4 free from irregularities are facilitated, for example, coating by a spin coater at the time of forming the insulating material layer 4 can be finished only with one coating. Further, it is possible to prevent a problem in exposure and development (exposure blur) of a photosensitive resist used in forming a wiring layer 5 and so on.

### Third Embodiment

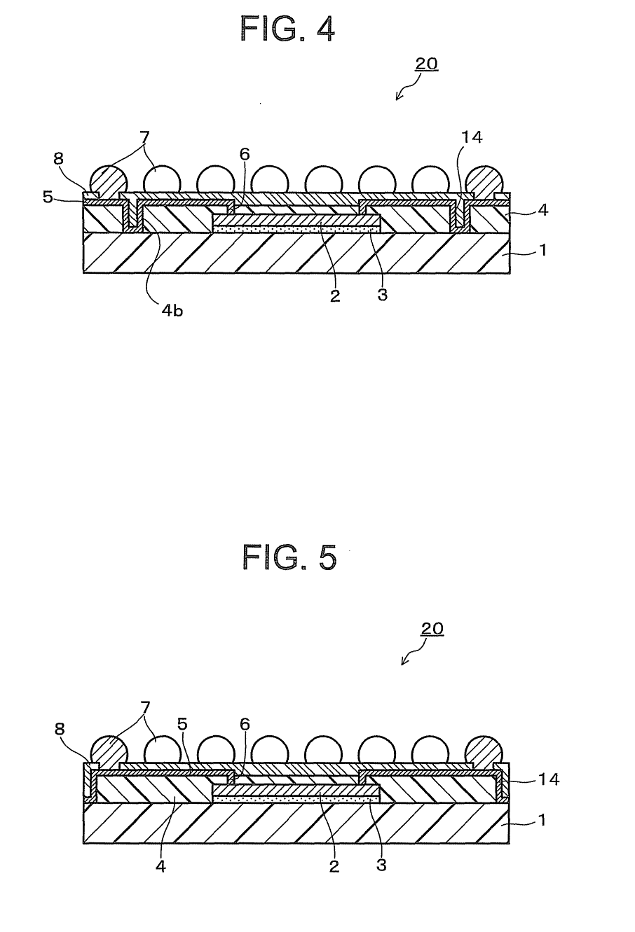

FIG. 4 is a cross-sectional view showing a third embodiment. The third embodiment has a flat plate 1 made of metal. The flat plate 1 may be a plate which is made of a resin cured substance and whose main surface on which a semiconductor chip 2 is fixedly bonded is metallized. In an insulating material layer 4 formed on the main surface of the flat plate 1, openings 4b whose bottom portions reach the main surface of the flat plate 1 are formed in an area surrounding the semiconductor chip 2. In the openings 4b, a conductive metal layer is formed so as to cover the flat plate 1 exposed to the bottom portions of the openings 4b, and grounding via parts 14 electrically connected to the flat plate 1 are formed. The grounding via parts 14 are connected to a wiring layer 5 formed on the insulating material layer 4 and are connected to ground electrode pads of the semiconductor chip 2 with via parts 6. Further, the grounding via parts 14 are connected to solder balls 7 being ground electrodes of external terminals, via the wiring layer 5. Note that the grounding via parts 14 only need to be connected to either the ground electrode pads of the semiconductor chip 2 or the solder balls 7 being the ground electrodes of the external terminals. In the third embodiment, the other parts are structured similarly to those of the first embodiment, and therefore description thereof will be omitted.

In the third embodiment, since the grounding via parts 14 connected to the ground electrode pads of the semiconductor chip 2 and/or the solder balls 7, which are the ground electrodes of the external terminals, via the wiring layer 5 are formed in the peripheral area of the semiconductor chip 2, EMI noise caused by electromagnetic interference (hereinafter, referred to as EMI) can be reduced.

In the semiconductor device 20 shown in FIG. 4, the grounding via parts 14 are formed on an inner side of an outer peripheral end surface of the semiconductor device 20, in the peripheral area outside of the semiconductor chip 2, but another alternative structure may be that the grounding via parts 14 are formed so as to be aligned with positions where the semiconductor device 20 is cut out and separated and the grounding via parts 14 are exposed to the outer peripheral end surface of the semiconductor device 20, as shown in FIG. 5.

### Fourth Embodiment

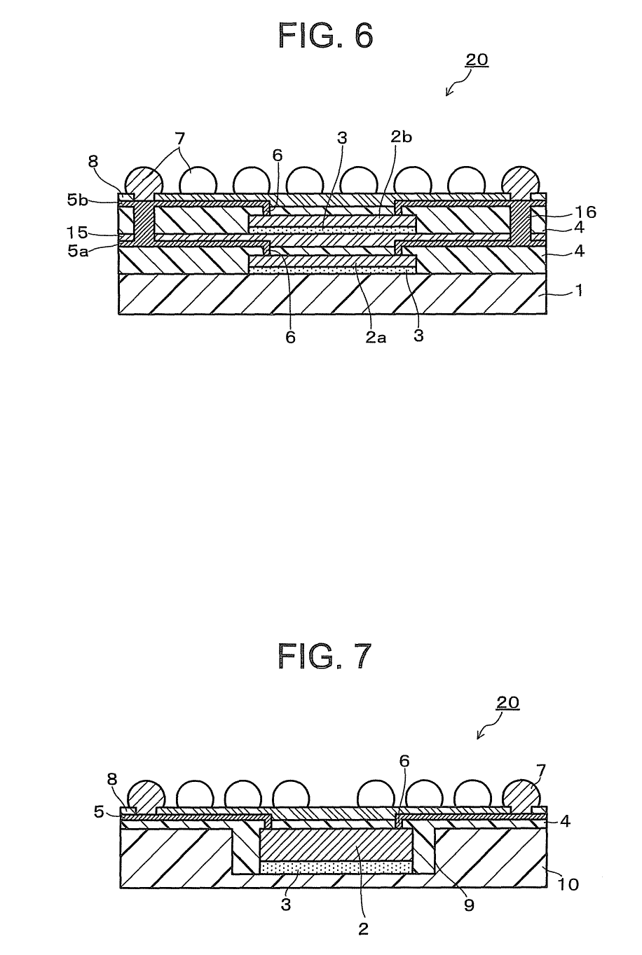

FIG. 6 is a cross-sectional view showing a fourth embodiment. A semiconductor device 20 of the fourth embodiment has a structure in which two semiconductor chips 2 (a first semiconductor chip 2a and a second semiconductor chip 2b) are mounted in a stacked manner. On one main surface of a flat plate 1, the first semiconductor chip 2a is fixedly bonded with an element circuit surface thereof facing upward, and an insulating material layer (a first insulating material layer) 4 is formed thereon so as to cover the first semiconductor chip 2a, and on the insulating material layer 4, a first wiring layer 5a having via parts 6 above electrode pads of the first semiconductor chip 2a is formed. An interlayer insulating protection layer 15 is formed on the first insulating material layer 4 and on the first wiring layer 5a except connection parts of later-described interlayer via parts.

Further, on the interlayer insulating protection layer 15, the second semiconductor chip 2b is fixedly bonded with an element circuit surface thereof facing upward, and an insulating material layer (a second insulating material layer) 4 is formed so as to cover the second semiconductor chip 2b. A second insulating material may be of the same type as or of a different type from a first insulating material.

A second wiring layer 5b is formed on the second insulating material layer 4, and via parts 6 electrically connecting the second wiring layer 5b and electrode pads of the second semiconductor chip 2b are formed. Further, in a peripheral area of the second semiconductor chip 2b, openings are formed in the second insulating material layer 4 so as to be aligned with via connection parts opened and formed in the interlayer insulating protection layer 15, and interlayer via parts 16 electrically connecting the first wiring layer 5a and the second wiring layer 5b are formed in the openings. Further, at predetermined positions of the second wiring layer 5b, solder balls 7 being external electrodes are formed in a grid array arrangement, and a solder resist layer 8 is formed on the second insulating material layer 4 and on the second wiring layer 5b except joint portions of the solder balls 7.

In the fourth embodiment as structured above, a semiconductor device having the structure in which the two semiconductor chips 2 (the first semiconductor chip 2a and the second semiconductor chip 2b) are mounted in a stacked manner, having high reliability in connection between the electrode pads of the semiconductor chips 2 and the wiring layers, and adaptable to the miniaturization of the electrodes can be obtained with high yields and at low cost.

The structure in which the two semiconductor chips 2 are mounted in a stacked manner is shown in the fourth embodiment. A structure in which three or more semiconductor chips are mounted in a stacked manner may be adopted. In the stacked structure of the three or more semiconductor chips, a structure similar to the above-described stacked structure of the second semiconductor chip 2b, the second insulating material layer 4, the second wiring layer 5b, and the interlayer via parts 16 is stacked on the second wiring layer 5b in number equal to the number of the semiconductor chips. Then, a solder resist layer is formed on the uppermost wiring layer and solder balls 7 are formed at predetermined positions, whereby the semiconductor device is completed.

### Fifth Embodiment

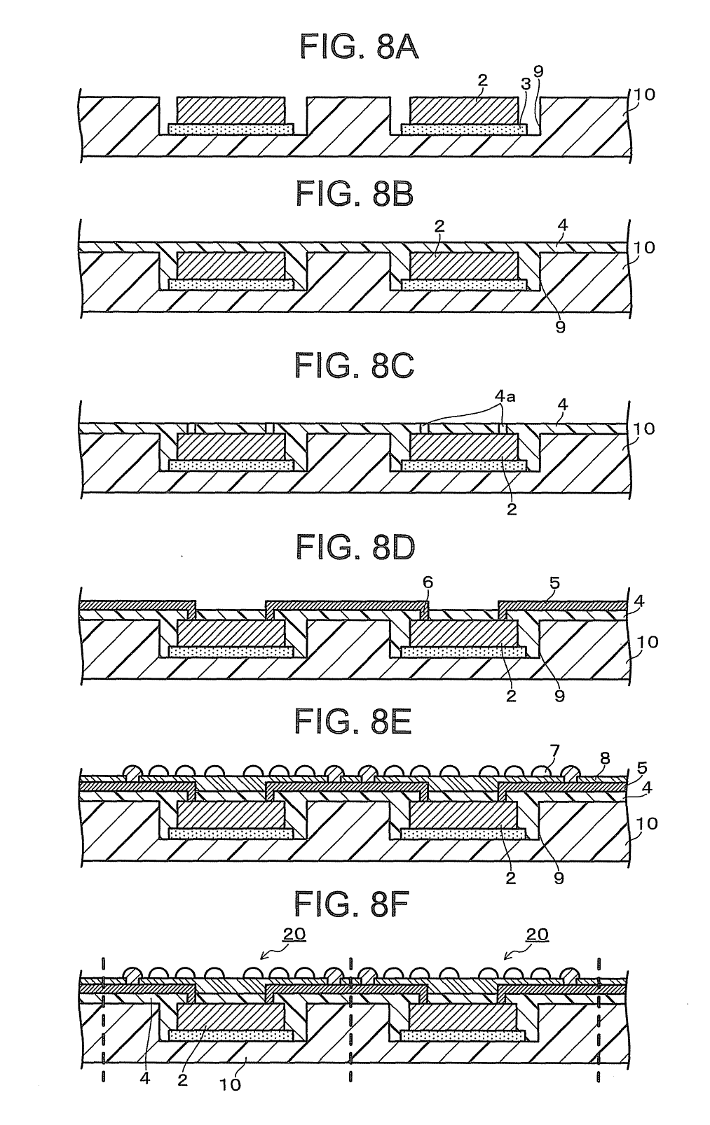

FIG. 7 is a cross-sectional view showing a semiconductor device according to a fifth embodiment of the present invention, and FIG. 8A to FIG. 8F are cross-sectional views showing processes of a method of manufacturing the semiconductor device of the fifth embodiment.

A semiconductor device 20 of the fifth embodiment shown in FIG. 7 includes a cavity-formed flat plate 10 which has a cavity (concave portion) 9 larger in planar size than a semiconductor chip 2 in one surface of a flat plate made of a resin cured substance or metal and having a uniform thickness. In the cavity 9 of the cavity-formed flat plate 10, one semiconductor chip 2 determined as non-defective in an electric characteristic test is disposed, with its surface opposite its element circuit surface being bonded and fixed on a bottom surface of the cavity 9 by an adhesive 3. The depth of the cavity 9 is adjusted according to the thickness of the semiconductor chip 2 so that a height difference between the element circuit surface of the semiconductor chip 2 and the surface, of the cavity-formed flat plate 10, in which the cavity 9 is formed (hereinafter, referred to as a cavity formation surface) becomes equal to a later-described predetermined value or less. The shape of the cavity 9 may be a so-called edged shape where the bottom surface and sidewall surfaces meet at a substantially right angle, or may be a shape where the bottom surface and the sidewall surfaces are continuously formed to form curved surfaces, that is, a shape where connection portions between the bottom surface and the sidewall surfaces are rounded.

On the cavity formation surface being a main surface of the cavity-formed flat plate 10 and the bottom surface in the cavity 9, a single layer (one layer) of an insulating material layer 4 composed of a material different from the resin material forming the cavity-formed flat plate 10 is formed. The insulating material layer 4 is formed so as to cover the element circuit surface of the semiconductor chip 2 disposed in the cavity 9 and fill a gap around the semiconductor chip 2 in the cavity 9, and an upper surface thereof is formed as a smooth surface free from irregularities.

In the semiconductor device 20 of this embodiment, the depth of the cavity 9 is adjusted so that the difference in height between the element circuit surface of the semiconductor chip 2 disposed in the cavity 9 and the surface (cavity formation surface) of the cavity-formed flat plate 10 is 100 μm or less, more preferably 50 μm or less. Most desirably, the element circuit surface of the semiconductor chip 2 and the surface of the cavity-formed flat plate 10 have no step therebetween and are equal in height to each other (that is, are flush with each other). When there is a height difference, it is preferable that the height of the element circuit surface of the semiconductor chip 2 is larger than the height of the cavity formation surface of the cavity-formed flat plate 10 because this facilitates the formation of via openings.

When the height difference between the element circuit surface of the semiconductor chip 2 and the cavity formation surface of the cavity-formed flat plate 10 is 50 μm or less, it is possible to form a single layer of the insulating material layer 4 having a smooth surface free from irregularities only by one coating using a spin coater or the like. When the height difference, even if over 50 μm, is 100 μm or less, it is possible to form the insulating material layer 4 having the smooth surface free from irregularities, by repeating the coating by a spin coater or the like a plurality of times or by adopting a method of stacking an insulating material of a film type a plurality of times.

The semiconductor device 20 of the fifth embodiment can be manufactured in the following manner.

As shown in FIG. 8A, the cavity-formed flat plate 10 in which the plural cavities 9 having predetermined planar size and depth are formed in a predetermined arrangement is prepared, and the semiconductor chips 2 determined as non-defective in the electric characteristic test are disposed in the cavities 9 of the cavity-formed flat plate 10 one by one and rear surfaces of the semiconductor chips 2 are bonded and fixed on bottom surfaces of the cavities 9. The cavity-formed flat plate 10 can be manufactured in such a manner that, for example, predetermined areas of a main surface of a smooth plate having a uniform thickness are etched or counter-sunk to form the cavities 9. Another possible alternative for manufacturing is such that on a flat plate having a uniform thickness, a perforated plate made of a material of the same type as or of a different type from that of the flat plate and having a large number of holes corresponding to cavity portions is put and these plates are integrated.

Next, as shown in FIG. 8B, on the whole main surface of the cavity-formed flat plate 10 (the cavity formation surface and the bottom surfaces in the cavities), an insulating resin material such as photosensitive epoxy resin is applied (coated) by using, for example, a spin coater so as to cover the element circuit surfaces of the semiconductor chips 2 and fill the gaps around the semiconductor chips 2 in the cavities 9. In this manner, a single layer (one layer) of the insulating material layer 4 having the smooth surface free from irregularities is formed.

After an insulating material layer-covered body in which the insulating material layer 4 is thus collectively formed on the main surface of the cavity-formed flat plate 10 is cut and processed into a predetermined shape (for example, a circular wafer shape), openings 4a are formed in the insulating material layer 4 above electrode pads of the semiconductor chips 2 by photolithography as shown in FIG. 8C. Next, by electrolytic plating followed by patterning using photolithography, a wiring layer 5 is formed on the insulating material layer 4 and via parts 6 electrically connecting the electrode pads of the semiconductor chips 2 and the wiring layer 5 in the openings 4a are formed as shown in FIG. 8D.

Next, as shown in FIG. 8E, a solder resist layer 8 is formed on the insulating material layer 4 and on predetermined areas on the wiring layer 5 except connection pads of external electrodes, and thereafter external electrodes such as solder balls 7 are formed on openings of the solder resist layer 8 (on the connection pads of the external electrodes).

Thereafter, as shown in FIG. 8F, the cavity-formed flat plate 10, the insulating material layer 4, and so on are cut at positions between the cavities 9, whereby the semiconductor devices 20 are separated from one another. In this manner, the semiconductor device 20 of the fifth embodiment is completed.

When the completed semiconductor device 20 has too large a thickness because of reasons that the thickness of the cavity-formed flat plate 10 is made large for warpage prevention, it is also possible to reduce the thickness of the semiconductor device 20 by, for example, mechanically polishing a surface opposite the cavity formation surface of the cavity-formed flat plate 10 before the semiconductor devices 20 are cut out and separated from one another.

In the semiconductor device 20 of the fifth embodiment thus manufactured, the semiconductor chip 2 is disposed in the cavity 9 of the cavity-formed flat plate 10, which makes it possible to reduce a height difference between the element circuit surface of the semiconductor chip 2 and the surface (cavity formation surface) of the cavity-formed flat plate 10 (for example, 50 μm or less) even when the thickness of the semiconductor chip 2 is as large as, for example, 20 μm or more. Therefore, the surface of the insulating material layer 4 which is formed only with one layer in the cavity 9 and on the cavity-formed flat plate 10 so as to cover the element circuit surface of the semiconductor chip 2 can be formed as a smooth surface free from irregularities, which makes it possible to prevent a problem in exposure and development (exposure blur) of a photosensitive resist used in forming the wiring layer 5 and so on and to form the wiring layer with a good characteristic.

Further, as in the semiconductor device of the first embodiment, since the insulating material layer 4 is a single layer formed by one coating process by using the photosensitive material different from the material forming the flat plate 1 and the number of such an insulating material layer 4 is only one, it is possible to simplify a formation process, improve yields, and reduce a stress in a package ascribable to a difference in coefficient of thermal expansion among the constituent materials, compared with a structure having two layers or more of the insulating material layers.

Further, since no positional deviation occurs between the electrode pads of the semiconductor chip 2 and the via parts 6, it is possible to obtain the high-yield, high-reliability semiconductor device 20 adaptable to miniaturization at low cost. Furthermore, since the wiring layer 5 is formed also on a peripheral area of the semiconductor chip 2 and the solder balls 7 being the external electrodes can be disposed on this area, it is possible to cope with the miniaturization of the electrode pads and arbitrarily design the pitch and number of the BGA balls.

Even more, the cavity-formed flat plate 10 in which the plural cavities 9 having predetermined planar size and depth are formed in a predetermined arrangement is used and a reinforcing effect by thick portions of the cavity-formed flat plate 10 is obtained, it is possible to prevent warpage ascribable to curing shrinkage of resin forming the insulating material layer 4 and heat strain between different types of materials.

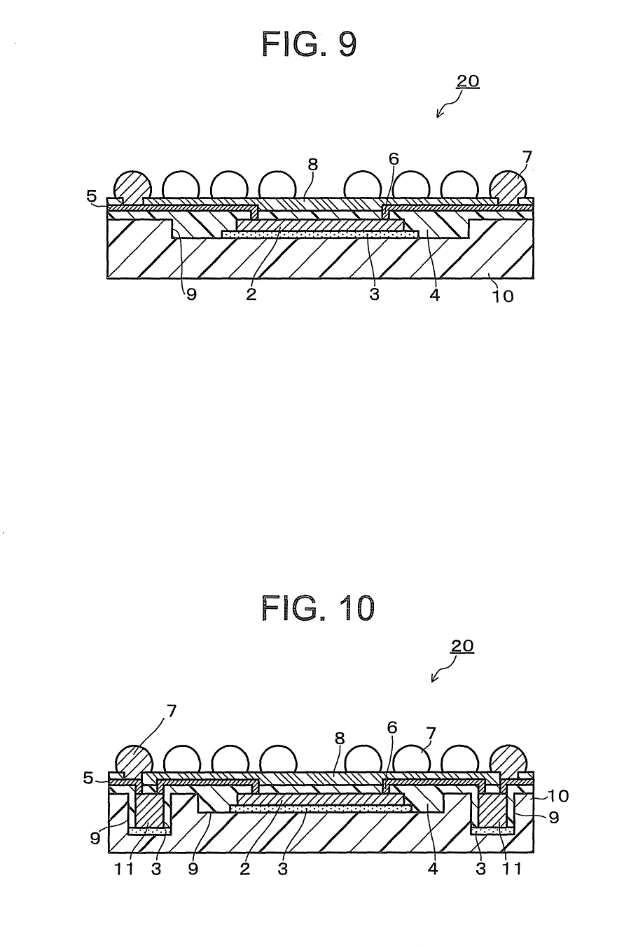

Sixth to tenth embodiments of the present invention will be described. FIG. 9 to FIG. 13 are cross-sectional views showing semiconductor devices according to the sixth to tenth embodiments of the present invention respectively.

### Sixth Embodiment

The semiconductor device 20 of the sixth embodiment shown in FIG. 9, includes a cavity-formed flat plate 10 having a large-sized cavity 9. The cavity 9 of the cavity-formed flat plate 10 is formed to have a planar size far larger than that of a semiconductor chip 2, so that a sufficiently wide gap around the semiconductor chip 2 disposed in the cavity 9 is formed. Further, this cavity 9 is formed shallower than the cavity 9 of the fifth embodiment. In such a large-sized, shallow cavity 9, the semiconductor chip 2 thinner than the semiconductor chip 2 mounted in the fifth embodiment is disposed and is bonded by an adhesive 3. The thickness of the thin semiconductor chip 2 is preferably 50 μm or less. Further, a height difference between an element circuit surface of the semiconductor chip 2 and a surface (cavity formation surface) of the cavity-formed flat plate 10 is equal to a predetermined value or less (100 μm or less, more preferably 50 μm or less). The element circuit surface of the semiconductor chip 2 and the surface of the cavity-formed flat plate 10 are most desirably equal to each other in height.

On a main surface of the cavity-formed flat plate 10, a single layer (one layer) of an insulating material layer 4 made of a material different from a material forming the cavity-formed flat plate 10 is formed. The insulating material layer 4 is formed so as to cover the element circuit surface of the semiconductor chip 2 disposed in the cavity 9 and fill a gap around the semiconductor chip 2 in the cavity 9, and has a smooth surface free from irregularities. The other parts in the sixth embodiment are structured similarly to those of the first embodiment, and therefore description thereof will be omitted.

In the sixth embodiment, since the planar size of the cavity 9 is far larger than that of the semiconductor chip 2 disposed in the cavity 9 and thus a sufficiently wide gap is formed between an inner wall surface of the cavity 9 and the semiconductor chip 2, a dent is less likely to be formed in a surface of the insulating material layer 4 flowing into this gap. Therefore, it is possible to more smooth the surface (upper surface) of the insulating material layer 4 than that of the fifth embodiment, which makes it possible to prevent a problem in exposure and development (exposure blur) of a photosensitive resist used in forming a wiring layer 5 and so on, and to form a wiring layer with a good characteristic.

Further, in the sixth embodiment, since the cavity-formed flat plate 10 having the cavity 9 having a large planar size is used, general versatility of the semiconductor chip 2 disposable and housable in the cavity 9 is high. That is, it is possible to dispose any of the semiconductor chips 2 with various planar sizes. Further, this embodiment is adaptable not only to the semiconductor chip 2 whose thickness is as thin as 50 μm or less but also to the semiconductor chips 2 with various thicknesses.

### Seventh Embodiment

In the semiconductor device 20 of the seventh embodiment shown in FIG. 10, a semiconductor chip 2 and a plurality of (for example, two) passive chip components 11 (for example, chip capacitors or the like) thicker than the semiconductor chip 2 are mounted on a cavity-formed flat plate 10. In the cavity-formed flat plate 10, three cavities 9 whose depths are set according to the thicknesses of the semiconductor chip 2 and the two passive chip components 11 (hereinafter, the semiconductor chip 2 and the chip passive components 11 are collectively called chip components) are provided, and the three chip components are disposed in the cavities 9 corresponding thereto respectively and bonded and fixed by an adhesive 3. Height differences between element circuit surfaces (upper surfaces) of the respective chip components disposed in the respective cavities 9 and a surface (cavity formation surface) of the cavity-formed flat plate 10 are set equal to a predetermined value or less (100 μm or less, more preferably 50 μm or less). The height differences for all the chip components are preferably equal to one another. Further, it is preferable that the height of upper surfaces of the chip components and the surface of the cavity-formed flat plate 10 are equal to each other, whereby the height difference is made zero.

On main surfaces (the cavity formation surface and bottom surfaces in the cavities 9) of the cavity-formed flat plate 10, a single layer (one layer) of an insulating material layer 4 made of a material different from a material forming the cavity-formed flat plate 10 is formed. The insulating material layer 4 is formed so as to cover the element circuit surfaces of the three chip components (the single semiconductor chip 2 and the two passive chip components 11) disposed in the respective cavities 9 and fill gaps around the chip components in the respective cavities 9, and the insulating material layer 4 is formed to have a smooth surface free from irregularities. The other parts in the seventh embodiment are structured similarly to those of the first embodiment, and therefore description thereof will be omitted.

In the semiconductor device 20 of the seventh embodiment, when the plural chip components different in thickness are mounted, it is possible to make the height differences between the element circuit surfaces of the chip components and the surface (cavity formation surface) of the cavity-formed flat plate 10 uniform and small (for example, 50 μm or less), and in addition, the insulating material layer 4 formed with the single layer (one layer) can be a layer having a smooth surface free from irregularities. This can prevent a problem in exposure and development (exposure blur) of a photosensitive resist formed on the insulating material layer 4 and to form a wiring layer 5 with a good characteristic.

Though the seventh embodiment shows the example where the three chip components (the one semiconductor chip 2 and the two passive chip components 11) are assembled, it is also possible to assemble totally two chip components including one semiconductor chip 2 or totally four chip components or more including one semiconductor chip 2 or more.

### Eighth Embodiment

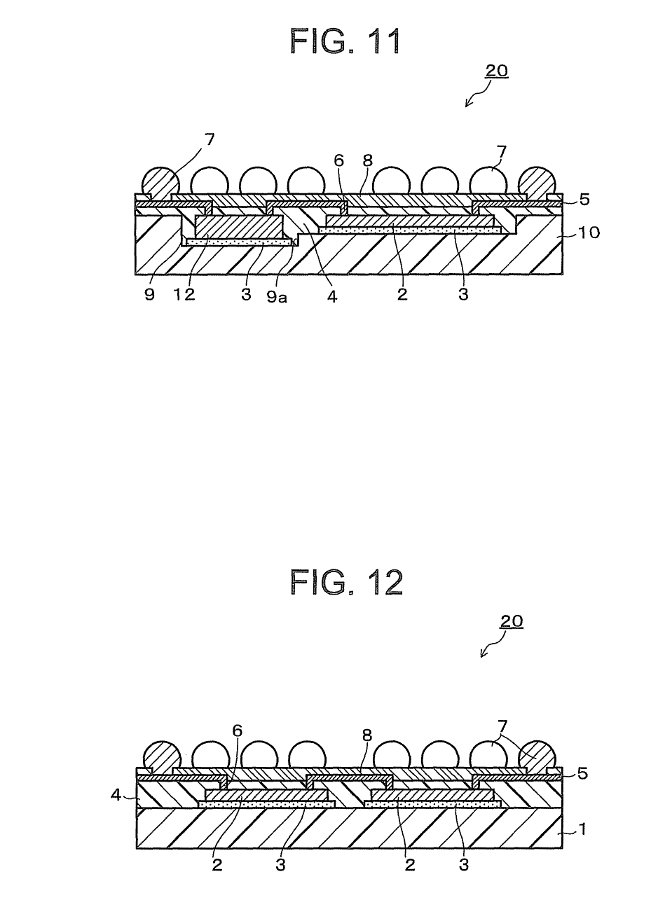

In a semiconductor device 20 of the eighth embodiment shown in FIG. 11, two chip components different in thickness, that is, a semiconductor chip 2 and a chip component 12 (a semiconductor chip or a passive chip component such as a chip capacitor), larger in thickness than the semiconductor chip 2, are disposed in one cavity 9 of a cavity-formed flat plate 10. A step 9a is formed in the cavity 9 and the step 9a separates the cavity 9 into a lower step portion and an upper step portion. The thick chip component 12 is bonded and fixed on a bottom surface of the lower step portion, and the semiconductor chip 2 thinner than the chip component 12 is bonded and fixed on a bottom surface of the upper step portion. Further, height differences between element circuit surfaces (upper surfaces) of the chip components and a surface (cavity formation surface) of the cavity-formed flat plate 10 are set to a predetermined value or less (100 μm or less, more preferably 50 μm or less). Preferably, the height differences for all the chip components are equal to one another and the upper surfaces of the chip components and the surface of the cavity-formed flat plate 10 have the same height.

On the cavity formation surface, which is a main surface of the cavity-formed flat plate 10, and on a bottom surface in the cavity, a single layer (one layer) of an insulating material layer 4 made of a material different from a material forming the cavity-formed flat plate 10 is formed. The insulating material layer 4 is formed so as to cover the element circuit surfaces of the two chip components (the semiconductor chip 2 and the thick chip component 12) disposed in the one cavity 9 and fill gaps around the chip components in the cavity 9, and the insulating material layer 4 is formed to have a smooth surface free from irregularities. The other parts in the eighth embodiment are structured similarly to those of the first embodiment, and therefore description thereof will be omitted.

In the semiconductor device 20 of the eighth embodiment, it is possible to make the height differences between the element circuit surfaces of the two chip components having different heights and the surface (cavity formation surface) of the cavity-formed flat plate 10 uniform and small (for example 50 μm or less), and in addition, the insulating material layer 4 formed thereon with the single layer can be a layer having a smooth surface free from irregularities. This can prevent a problem in exposure and development (exposure blur) of a photosensitive resist formed on the insulating material layer 4 and to form a wiring layer 5 with a good characteristic.

Though the eighth embodiment shows the example where the two chip components (the semiconductor chip 2 and the chip component 12 thicker than the semiconductor chip 2) are assembled in the one cavity 9, it is also possible to assemble three chip components or more including one semiconductor chip or more in the one cavity 9.

### Ninth and Tenth Embodiments

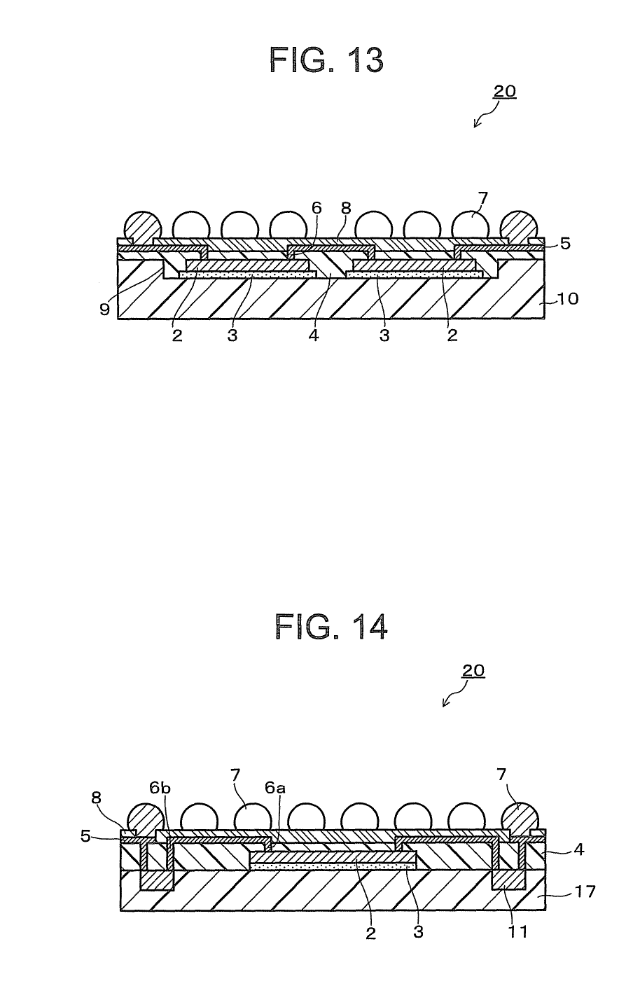

The ninth embodiment shown in FIG. 12 and the tenth embodiment shown in FIG. 13 show semiconductor devices of a multi-chip module type.

In the ninth embodiment shown in FIG. 12, on a main surface of a flat plate 1 having a uniform thickness, two semiconductor chips 2 having an equal thickness of 20 μm or less are disposed with element circuit surfaces thereof facing upward, and rear surfaces thereof are bonded and fixed by an adhesive 3. The height from the main surface (semiconductor chip mounting surface) of the flat plate 1 to the element circuit surfaces of the semiconductor chips 2 is set to 100 μm or less, more preferably 50 μm or less. Further, on the whole main surface of the flat plate 1, a single layer (one layer) of an insulating material layer 4 having a smooth surface free from irregularities is formed so as to cover the element circuit surfaces of the two semiconductor chips 2. The other parts in the ninth embodiment are structured similarly to those of the first embodiment, and therefore description thereof will be omitted.

In the tenth embodiment shown in FIG. 13, two semiconductor chips 2 equal in thickness are disposed in one cavity 9 of a cavity-formed flat plate 10, and are bonded and fixed on a bottom surface of the cavity 9 by an adhesive 3. A height difference between the element circuit surfaces of the two semiconductor chips 2 and a surface (cavity formation surface) of the cavity-formed flat plate 10 is set to a predetermined value or less (100 μm or less, more preferably 50 μm or less). Further, on the cavity formation surface being the main surface of the cavity-formed flat plate 10 and on the bottom surface of the cavity 9, a single layer (one layer) of an insulating material layer 4 is formed so as to cover the element circuit surfaces of the two semiconductor chips 2. The insulating material layer 4 is filled also in gaps around the two semiconductor chips 2 in the cavity 9, and a layer having a smooth surface free from irregularities is formed. The other parts in the tenth embodiment are structured similarly to those of the first embodiment, and therefore description thereof will be omitted.

In the ninth embodiment and the tenth embodiment as structured above, it is possible to obtain a high-yield, high reliability semiconductor device of a multi-chip module type at low cost. Further, it is possible to arbitrarily design the pitch and number of BGA balls, which makes it possible to cope with the miniaturization of electrode pads.

### Eleventh Embodiment

A semiconductor device 20 of the eleventh embodiment shown in FIG. 14 includes a component-buried flat plate 17 which is made of a resin cured substance and in which chip components 11 such as passive chip components are buried at predetermined positions. The chip components 11 are buried so that their electrode terminals (not shown) are exposed to one main surface of the component-buried flat plate 17. At a predetermined position of the main surface of the component-buried flat plate 17, a semiconductor chip 2 is disposed with its element circuit surface facing upward and is fixedly bonded by an adhesive 3. On the whole main surface of the component-buried flat plate 17, a single layer (one layer) of an insulating material layer 4 is formed so as to cover electrode terminal exposed portions of the chip components 11 and an element circuit surface of the semiconductor chip 2, and on the insulating material layer 4, a wiring layer 5 made of conductive metal such as copper is formed. Further, in the insulating material layer 4 formed on the element circuit surface of the semiconductor chip 2, openings are formed. In the openings, first via parts 6a electrically connecting electrode pads (not shown) of the semiconductor chip 2 and the wiring layer 5 are formed. Further, openings are also formed in the insulating material layer 4 formed above the electrode terminal exposed portions of the chip components 11. In these openings, second via parts 6b electrically connecting the electrode terminals of the chip components 11 and the wiring layer 5 are formed. The first via parts 6a and the second via parts 6b are both formed collectively with the wiring layer 5.

Further, on the insulating material layer 4 and on the wiring layer 5 except predetermined connection portions, a solder resist layer 8 is formed, and at predetermined positions on the wiring layer 5, a plurality of solder balls 7 being external electrodes are formed.

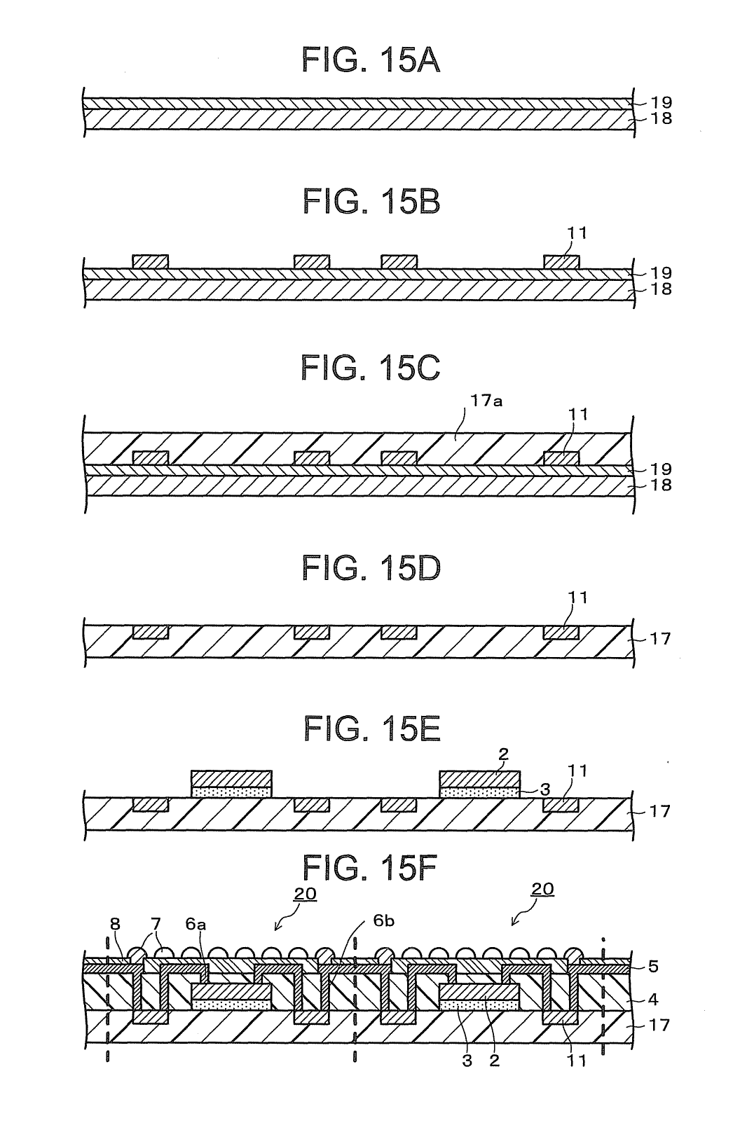

The semiconductor device 20 of the eleventh embodiment can be manufactured as follows. As shown in FIG. 15A, a pressure-sensitive adhesive double coated tape 19 is affixed on one surface of a support substrate 18 such as a glass plate or the like which is sufficiently smooth and has rigidity, and thereafter, as shown in FIG. 15B, the plural chip components 11 are positioned and affixed on an adhesive layer of the pressure-sensitive adhesive double coated tape 19 with electrode terminal formation surfaces thereof facing downward.

Next, as shown in FIG. 15C, on the support substrate 18 on which the chip components 11 are affixed, insulating resin 17a such as, for example, mold resin, is molded into a flat plate shape having a uniform thickness and a flat surface. In this molding of the flat plate, positions of the electrode terminals of the chip components 11 and via part formation positions of an exposure mask used for forming later-described via openings sometimes deviate from each other due to the shrinkage of the insulating resin 17a when it cures, but since the diameters of the electrode terminals of the chip components 11 are large, there occurs no failure in electric connection between the electrode terminals of the chip components 11 and the second via parts 6b even if the positional deviation occurs. Next, as shown in FIG. 15D, the pressure-sensitive adhesive double coated tape 19 is peeled off and the support substrate 18 is removed, whereby the component-buried flat plate 17 in which the chips 11 are buried is obtained.

As shown in FIG. 15E, on a main surface (a surface to which the electrode terminals of the chip components 11 are exposed) of the component-buried flat plate 17, the semiconductor chips 2 are fixedly bonded by an adhesive 3. Then, as shown in FIG. 15F, in the same manner as the manner for manufacturing the semiconductor device of the first embodiment, formation of the insulating material layer 4, the formation of the via openings in the insulating material layer 4 on electrode pads of the semiconductor chip 2 and on the electrode terminal exposed portions of the chip components 11, the collective formation of the first via parts 6a, the second via parts 6b, and the wiring layer 5, the formation of the solder resist layer 8, and the formation of the solder balls 7 are performed and thereafter, the component-buried flat plate 17, the insulating material layer 4, and so on are cut at positions between the semiconductor chips 2, thereby separating the semiconductor devices 20 from one another. The semiconductor device 20 of the eleventh embodiment is completed.

In the eleventh embodiment, it is possible to obtain a high-yield, high-reliability semiconductor device at low cost. Further, the pitch and number of the BGA balls can be arbitrarily designed, which makes it possible to cope with the miniaturization of the electrode pads.

### Twelfth Embodiment

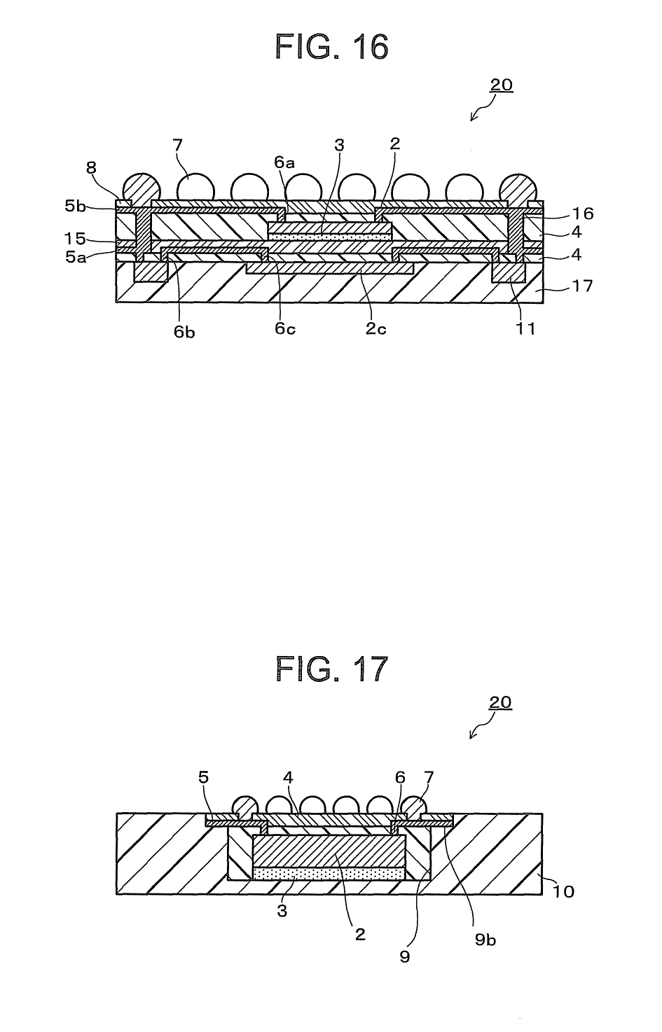

In the twelfth embodiment shown in FIG. 16, a semiconductor device of a multi-chip module type is shown. The semiconductor device of the twelfth embodiment includes a component-buried flat plate 17 which is made of a resin cured substance and in which not only chip components 11 such as passive components but also a large-pitch semiconductor chip 2c is buried. In the large-pitch semiconductor chip 2c, the pitch between electrode pads (not shown) is relatively large (for example, a pitch dimension is over 80 μm), and the large-pitch semiconductor chip 2c is buried so that the electrode pads are exposed from one main surface of the component-buried flat plate 17.

The component-buried flat plate 17 can be molded in the same manner as the manner for molding the component-buried flat plate 17 in the eleventh embodiment. In the molding, the shrinkage of mold insulating resin when it is cured sometimes causes the deviation between positions of the electrode pads of the large-pitch semiconductor chip 2c and via formation positions of an exposure mask used for forming via openings, but since the pitch dimension between the electrode pads of the large-pitch semiconductor chip 2c is larger than that of a common semiconductor chip, there occurs no failure in electric connection between the electrode pads and via parts even if the positional deviation occurs.

On the whole main surface of the component-buried flat plate 17 as structured above, a single layer (one layer) of an insulating material layer (first insulating material layer) 4 is formed so as to cover electrode terminal exposed portions of the chip components 11 and electrode pad exposed portions of the large-pitch semiconductor chip 2c, and on the insulating material layer 4, a first wiring layer 5a made of conductive metal such as copper is formed. Further, at predetermined positions of the first insulating material layer 4, a plurality of openings are formed, and in these openings, conductive metal is filled. Second via parts 6b, which electrically connect the electrode terminals of the chip components 11 and the first wiring layer 5a, and third via parts 6c, which electrically connect the electrode pads of the large-pitch semiconductor chip 2c and the wiring layer 5, are formed. The second via parts 6b and the third via parts 6c are both collectively formed with the wiring layer 5.

Further, on the first insulating material layer 4 and on the first wiring layer 5a except connection parts of later-described interlayer via parts (via connection parts), an interlayer insulating protection layer 15 is formed. Further, on the interlayer insulating protection layer 15, a semiconductor chip 2 in which the pitch between electrode pads is smaller than that of the large-pitch semiconductor chip 2c (for example, the pitch dimension is 50 μm) is fixedly bonded by an adhesive 3 with its element circuit surface facing upward, and a single layer (one layer) of an insulating material layer (second insulating material layer) 4 is formed on the interlayer insulating protection layer 15 so as to cover the element circuit surface of the semiconductor chip 2.

On the second insulating material layer 4, a second wiring layer 5b is formed, and via parts 6a electrically connecting the wiring layer 5b and the electrode pads of the semiconductor chip 2 are formed collectively with the wiring layer 5b. Further, in a peripheral area of the second insulating material layer 4, openings are formed so as to be aligned with the via connection parts opened and formed in the interlayer insulating protection layer 15, and in these openings, interlayer via parts 16 electrically connecting the first wiring layer 5a and the second wiring layer 5b are formed. Further, at predetermined positions of the second wiring layer 5b, solder balls 7 being external electrodes are formed in a grid array arrangement, and a solder resist layer 8 is formed on the second insulting material layer 4 and on the second wiring layer 5b except joint portions of the solder balls 7.

In the twelfth embodiment thus structured, it is possible to obtain a high-yield, high-reliability semiconductor device of a multi-chip module type at low cost. Further, the pitch and number of the BGA balls can be arbitrarily designed, which makes it possible to cope with the miniaturization of the electrode pads.

### Thirteenth Embodiment

In the thirteenth embodiment shown in FIG. 17, a cavity-formed flat plate 10 made of metal which has a cavity (concave portion) 9 having a stepped portion 9b in its periphery is used. In the cavity 9 of the cavity-formed flat plate 10, a semiconductor chip 2 is disposed with its element circuit surface facing upward, and its opposite surface is bonded and fixed by an adhesive 3. In the cavity-formed flat plate 10, the depth of the cavity 9 and the height of the stepped portion 9b are adjusted so that the stepped portion 9b of the cavity 9 is located higher than the element circuit surface of the semiconductor chip 2 and a height difference between the stepped portion 9b and the element circuit surface of the semiconductor chip 2 becomes 100 μm or less, more preferably, 50 μm or less.

In the cavity 9 of the cavity-formed flat plate 10, a single layer (one layer) of an insulating material layer (first insulating material layer) 4 is formed so as to cover the element circuit surface of the semiconductor chip 2 disposed in the cavity 9 and so as to fill a gap around the semiconductor chip 2. The first insulating material layer 4 is formed so that its upper surface becomes equal in height to the stepped portion 9b in the cavity 9.

On the first insulating material layer 4, a wiring layer 5 made of conductive metal such as copper is formed, and via parts 6 electrically connecting the wiring layer 5 and electrode pads (not shown) of the semiconductor chip 2 are formed collectively with the wiring layer 5. Further, part of the wiring layer 5 connected to ground electrode pads of the semiconductor chip 2 via the via parts 6 extends to an area on the stepped portion 9b in the cavity 9 and thus is led out to a peripheral area of the semiconductor chip 2. The wiring layer 5 thus led out is connected to the cavity-formed flat plate 10 at the stepped portion 9b. Further, the wiring layer 5 connected to the cavity-formed flat plate 10 is connected to solder balls 7 being ground electrodes of external terminals. Incidentally, the wiring layer 5 only needs to be connected either to the ground electrode pads of the semiconductor chip 2 or to the solder balls 7 being the ground electrodes of the external terminals.

Further, an insulating material layer (second insulating material layer) 4 having opening portions at predetermined positions is formed on the wiring layer 5 so as to fill a portion, of the cavity 9, higher than the stepped portion 9b, and a cavity formation surface being a main surface of the cavity-formed flat plate 10 is not covered by the second insulating material layer 4 but is exposed. On the opening portions of the second insulating material layer 4, the solder balls 7 being the external electrodes are formed. The plural solder balls 7 are formed in a grid array arrangement. Incidentally, the second insulating material layer 4 can be a solder resist layer.

The semiconductor device 20 of the thirteenth embodiment as described above can be manufactured by as follows, for instance. Specifically, after a group of cavities 9 disposed in a predetermined arrangement is formed by etching or counter-sinking predetermined areas of a main surface of a metal flat plate having a uniform thickness, thick portions are formed in the flat plate in peripheral areas and center areas of the group of the cavities 9. As for the formation of the thick portions, they can be manufactured in such a manner that in the peripheral areas and the center areas of the flat plate where the group of the cavities 9 is formed, a perforated plate made of the same material or a different material and having a large number of opening portions corresponding to the cavities 9 is overlaid on and integrated with the flat plate. As a result, the metal cavity-formed flat plate 10 having the group of the cavities (concave portions) 9 each including the stepped portion 9b can be obtained.

Next, the semiconductor chips 2 are disposed on bottom portions of the respective cavities 9 of the cavity-formed flat plate 10, and liquid resin or the like is injected by a dispenser so as to fill a cavity lower portion which is lower than the stepped portion 9b (first sealing step). In this manner, one layer of the insulating material layer (first insulating material layer) 4 having a smooth surface free from irregularities is formed. Next, the wiring layer 5 is formed on the insulating material layer (first insulating material layer) 4, and after the via parts 6 connecting the wiring layer 5 and the electrode pads of the semiconductor chips 2 and grounding connection parts connected to the cavity-formed flat plate 10 are collectively formed, liquid resin or the like is injected for sealing so as to fill the cavity upper portion higher than the stepped portion 9b (second sealing step). In this manner, the insulating material layer (second insulating material layer) 4 having a smooth surface free from irregularities is formed on the wiring layer 5. Formation methods of the first and second insulating material layers 4 include, besides the method of dispensing the liquid resin, a method of applying a sheet material, a method of applying liquid resin by a method such as spin coating, printing, or the like, and so on.

Next, after the openings of the second insulating material layer 4 and the solder balls 7 are formed, the cavity-formed flat plate 10, the insulating material layer 4, and so on are cut at positions between the semiconductor chips 2, thereby separating the semiconductor devices 20 from one another. Consequently, the semiconductor device 20 of the thirteenth embodiment is completed.

In the semiconductor device 20 of the thirteenth embodiment as structured above, since the metal plate material whose peripheral and center portions are made thick is used as the cavity-formed flat plate 10, a reinforcement effect by the thick portions is obtained, which makes it possible to prevent warpage caused by curing shrinkage of the sealing resin and by thermal strain occurring between different kinds of materials. Further, since the cavities (concave portions) 9 of the cavity-formed flat plate 10 have the stepped portions 9b, the stepped portions 9b function as dams when liquid resin is used as a sealing material, which can prevent the flow of the liquid resin out of the cavities (concave portions) 9.

Further, the two-stage sealing steps (the formation processes of the insulating material layers 4) makes it possible to more completely eliminate the irregularities and steps on the upper surface of the insulating material layer 4, which makes it possible to eliminate problems such as thinning and wire breakage of the wiring layer 5 ascribable to a problem in exposure and development (exposure blur) of a photosensitive resist.

Furthermore, since the periphery of the semiconductor chip 2 disposed in the cavity 9 is surrounded by the thick portion, it is also possible to prevent the warpage also in the semiconductor device 20 after it is separated into an individual piece. Further, since the cavity formation surface being the main surface of the cavity-formed flat plate 10 is not covered by the second insulating material layer 4 but is exposed and the semiconductor chip 2 is surrounded by metal, a high electromagnetic wave shielding effect is obtained. Further, since the semiconductor device 20 is connected to the metal cavity-formed flat plate 10 which is grounded, by the wiring layer 5 extending to and formed in the stepped portion 9b in the cavity 9, an EMI reducing effect can be expected.

The structures, shapes, sizes, and arrangement relations described in the above embodiments are only roughly shown, and the compositions (materials) and so on of the components are only exemplary. Therefore, the present invention is not limited to the above embodiments, and the embodiments can be modified to various formed without departing from the scope of the technical idea shown in the claims.

What is claimed is:

1. A semiconductor device, comprising:
a flat plate;
a semiconductor chip which is disposed on one main surface of the flat plate and whose surface opposite an element circuit surface is fixedly bonded;
a single layer of an insulating material layer formed continuously on the element circuit surface of the semiconductor chip and on the main surface of the flat plate and composed of a material different from a material of the flat plate;
an opening formed at a position, in the insulating material layer, above an electrode disposed on the element circuit surface of the semiconductor chip;
a conductive part formed in the opening so as to be connected to the electrode of the semiconductor chip;
a wiring layer formed on the insulating material layer so as to be connected to the conductive part, and partly led out to a peripheral area of the semiconductor chip; and
external electrodes formed on the wiring layer.

2. The semiconductor device according to claim 1,
wherein the insulating material layer formed on the element circuit surface of the semiconductor chip has a thickness of 5 μm to 30 μm.

3. The semiconductor device according to claim 1,
wherein the conductive part and the wiring layer are integrated.

4. The semiconductor device according to claim 1,
wherein the external electrodes are arranged in a grid array on a whole area of the flat plate.

5. The semiconductor device according to claim 1,
wherein a step interpolation part is formed on the flat plate so as to surround an outer peripheral side surface of the semiconductor chip.

6. The semiconductor device according to claim 1,
wherein in the insulating material layer formed on a peripheral area of the semiconductor chip, a grounding opening reaching the main surface of the flat plate is formed, a grounding conductive part is formed in the grounding opening, and the grounding conductive part is connected to a ground electrode of the semiconductor chip and/or an ground electrode of the external electrode via the wiring layer.

7. The semiconductor device according to claim 6,
wherein the grounding conductive part is provided so as to be exposed to an outer peripheral end surface of the semiconductor device.

8. The semiconductor device according to claim 1,
wherein two semiconductor chips are disposed in a stacked manner in a thickness direction, with the insulating material layer and an interlayer insulating protection layer being interposed therebetween, and an interlayer via part connecting the wiring layers corresponding to the respective semiconductor chips is provided.

9. The semiconductor device according to claim 1,
wherein two or more semiconductor chips equal in thickness are disposed and fixedly bonded on the main surface of the flat plate having a uniform thickness, with element circuit surfaces facing upward.

10. The semiconductor device according to claim 1,
wherein the flat plate has one cavity or more, and chip components including one semiconductor chip or more are fixedly bonded on bottom portions of the respective cavities, heights of upper surfaces of the chip components from a surface, of the flat plate (the cavity-formed flat plate), where the cavities are formed are substantially equal to each other, and the insulating material layer is filled in gaps between the cavities and the chip components in the cavities.

11. The semiconductor device according to claim 10,
wherein the upper surface of the chip component and the surface, of the cavity-formed flat plate, where the cavity is formed are equal in height to each other (are flush with each other).

12. The semiconductor device according to claim 10,
wherein the semiconductor chip and a passive chip component thicker than the semiconductor chip are disposed separately in the cavities.

13. The semiconductor device according to claim 10,
wherein the cavity of the cavity-formed flat plate has a step, the semiconductor chip is disposed on an upper step portion of the cavity and a passive component thicker than the semiconductor chip is disposed in a lower step portion of the cavity.

14. The semiconductor according to claim 10,
wherein two semiconductor chips or more equal in thickness are disposed in the one cavity of the cavity-formed flat plate.

15. The semiconductor device according to claim 10,
wherein the cavity of the cavity-formed flat plate includes a conductive stepped portion, the wiring layer is connected to a ground electrode of the semiconductor chip and/or a ground electrode of the external electrode, and the wiring layer is connected to the conductive stepped portion of the cavity.

16. The semiconductor device according to claim 1,
wherein a large-pitch semiconductor chip in which a pitch of electrodes is larger than a pitch of electrodes of the semiconductor chip and/or a passive chip component are (is) buried in the flat plate with the electrodes being exposed, the semiconductor chip is disposed on the main surface of the flat plate, and a surface opposite the element circuit surface of the semiconductor chip is fixedly bonded.

17. A method of manufacturing a semiconductor device, comprising:
positioning and disposing a plurality of semiconductor chips on one main surface of a flat plate and fixedly bonding surfaces, of the semiconductor chips, opposite element circuit surfaces;
forming an insulating material layer composed of a material different from a material forming the flat plate, on the element circuit surfaces of the semiconductor chips and on the main surface of the flat plate;
forming openings in the insulating material layer at positions above electrodes disposed on the element circuit surfaces of the semiconductor chips;
forming, on the insulating material layer, a wiring layer partly led out to peripheral areas of the semiconductor chips, and forming, in the openings of the insulating material layer, conductive parts connected to the electrodes of the semiconductor chips;
forming external electrodes on the wiring layer; and
cutting the flat plate and the insulating material layer at predetermined positions to separate a semiconductor device including one or more of the semiconductor chips.

18. The method of manufacturing the semiconductor device according to claim 17,
wherein the forming the insulating material layer includes applying a photosensitive insulating resin material only once.

19. The method of manufacturing the semiconductor device according to claim 17,
wherein the forming the openings in the insulating material layer includes forming the openings by photolithography.

20. The method of manufacturing the semiconductor device according to claim 17,
wherein the forming the wiring layer and forming the conductive parts includes forming a conductive metal layer on a whole upper surface of the insulating material layer by electrolytic plating.
